(19) United States
(12) Patent Application Publication
(10) Pub. No.: US 2024/0250008 A1
(43) Pub. Date: Jul. 25, 2024

(54) SEMICONDUCTOR PACKAGE

(71) Applicant: SAMSUNG ELECTRONICS CO., LTD., SUWON-SI (KR)

(72) Inventors: JUSUK KANG, Suwon-si (KR); JU-IL CHOI, Suwon-si (KR); SUNG KEUN PARK, Suwon-si (KR); JONGHO PARK, Suwon-si (KR); HYUNJU LEE, Suwon-si (KR); JAEMOK JUNG, Suwon-si (KR)

(21) Appl. No.: 18/453,422

(22) Filed: Aug. 22, 2023

(30) Foreign Application Priority Data
Jan. 20, 2023 (KR) 10-2023-0008642

(51) Int. Cl. H01L 23/498; H01L 23/00; H01L 23/31; H01L 25/10

(52) U.S. Cl. CPC H01L 23/49822; H01L 23/3107; H01L 23/49838; H01L 23/49866; H01L 24/16; H01L 25/105; H01L 2224/16227; H01L 2224/16237; H01L 2224/16238; H01L 2225/1023; H01L 2225/1041; H01L 2225/1058; H01L 2924/35121

(57) ABSTRACT

A semiconductor package, comprising a redistribution substrate including an insulating layer and a first redistribution pattern; and a semiconductor chip electrically connected to the redistribution substrate, wherein the first redistribution pattern comprises a first barrier layer; a second barrier layer on the first barrier layer; and a via structure on the second barrier layer, wherein the first barrier layer comprises a first conductive material and the second barrier layer comprises a second conductive material different from the first conductive material.

### CROSS-REFERENCE TO RELATED APPLICATIONS

This application claims priority under 35 U.S.C. § 119 to Korean Patent Application No. 10-2023-0008642, filed on Jan. 20, 2023, in the Korean Intellectual Property Office, the disclosure of which is incorporated by reference herein in its entirety.

### BACKGROUND

The present disclosure relates to a semiconductor package, and in particular to a semiconductor package with a redistribution pattern.

A semiconductor package integrates an integrated-circuit chip into an electronic product. In general, the semiconductor package includes a printed circuit board (PCB) and a semiconductor chip. The semiconductor chip is mounted on the PCB and establishes an electrical connection using bonding wires or bumps. With the development of the semiconductor industry, numerous studies are being conducted to increase the reliability of the semiconductor package.

A semiconductor package may have a titanium (Ti) layer as an interface layer between copper (Cu) and polymer layers in the redistribution layer (RDL), under-bump metallization (UBM), pad, and passivation layers. However, gases outgassed from the polymer layer can cause the formation of an oxide layer (e.g., TiOx). The existence of this oxide layer can weaken the interfacial adhesion strength between the copper and polymer layers.

### SUMMARY

An embodiment of the present disclosure provides a semiconductor package including an insulating layer and a redistribution pattern, which are robustly attached to each other.

According to embodiments of the present disclosure, a semiconductor package, comprising a redistribution substrate including an insulating layer and a first redistribution pattern; and a semiconductor chip electrically connected to the redistribution substrate, wherein the first redistribution pattern comprises a first barrier layer; a second barrier layer on the first barrier layer; and a via structure on the second barrier layer, wherein the first barrier layer comprises a first conductive material and the second barrier layer comprises a second conductive material different from the first conductive material.

According to embodiments of the present disclosure, a semiconductor package includes a redistribution substrate including an insulating layer, a redistribution pattern, and a connection conductive pattern; a semiconductor chip electrically connected to the redistribution substrate; and a solder ball in contact with the connection conductive pattern, wherein the connection conductive pattern includes an under-bump including an upper portion and a lower portion having a width smaller than the upper portion; and a first barrier layer and a second barrier layer, wherein each of the first barrier layer and the second barrier layer surrounds the lower portion of the under-bump in a plan view, wherein the solder ball is in contact with a bottom surface of the lower portion of the under-bump.

According to embodiments of the present disclosure, a semiconductor package includes a first redistribution substrate including an insulating layer, a first redistribution pattern, a second redistribution pattern, and a connection conductive pattern; a first semiconductor chip mounted on the first redistribution substrate; a connection structure between the first semiconductor chip and the first redistribution pattern; and a solder ball connected to the connection conductive pattern, wherein each of the first and second redistribution patterns includes a first barrier layer; a second barrier layer on the first barrier layer; and a via structure on the second barrier layer, wherein the first barrier layer comprises titanium nitride (TiN), the second barrier layer includes titanium (Ti), the via structure comprises copper (Cu), and a thickness of the first barrier layer is smaller than a thickness of the second barrier layer.

### BRIEF DESCRIPTION OF THE DRAWINGS

FIG. 1A is a sectional view illustrating a semiconductor package according to an embodiment of the present disclosure.

FIG. 1B is a detailed view illustrating a portion ‘A’ of FIG. 1A.

FIG. 1C is a detailed view illustrating a portion ‘B’ of FIG. 1A.

FIG. 1D is a detailed view illustrating a portion ‘C’ of FIG. 1A.

FIGS. 2A, 2B, 2C, 2D, 2E, 2F, 2G, 2H, and 2I are sectional views illustrating a method of fabricating a semiconductor package according to an embodiment of the present disclosure.

FIG. 3A is a sectional view illustrating a semiconductor package according to an embodiment of the present disclosure.

FIG. 3B is a detailed view illustrating a portion ‘D’ of FIG. 3A.

FIG. 3C is a detailed sectional view illustrating a semiconductor package according to an embodiment of the present disclosure.

FIG. 4 is a detailed sectional view illustrating a semiconductor package according to an embodiment of the present disclosure.

FIG. 5 is a sectional view illustrating a semiconductor package according to an embodiment of the present disclosure.

FIG. 6 is a sectional view illustrating a semiconductor package according to an embodiment of the present disclosure.

### DETAILED DESCRIPTION

Embodiments of the present disclose provide a structure including a layer of titanium nitride (TiN), in addition to the titanium (Ti) layer, as an interface layer between the copper (Cu) and polymer layers. Specifically, the TiN layer may be disposed beneath the Ti layer to prevent the formation of an oxide layer (e.g., TiOx) within the Ti layer. Accordingly, this structure may mitigate the occurrence of interfacial delamination, thereby potentially reducing the risk of deteriorating the adhesion strength at the interface between the copper and polymer layers.

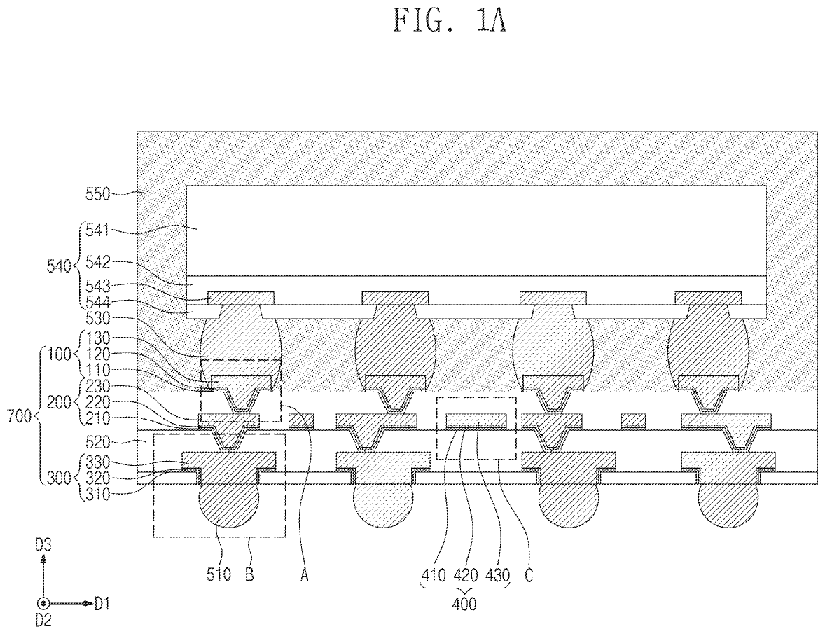

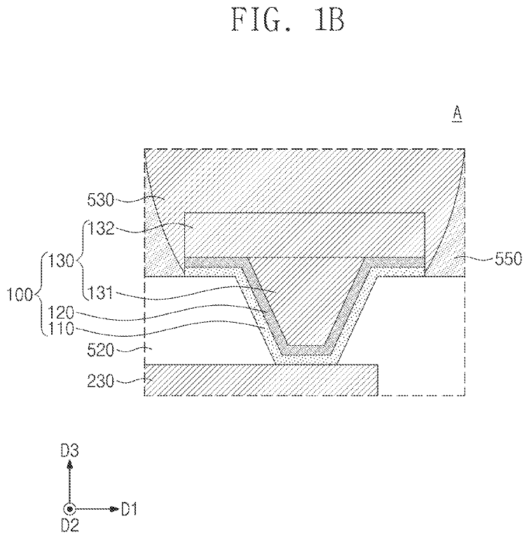

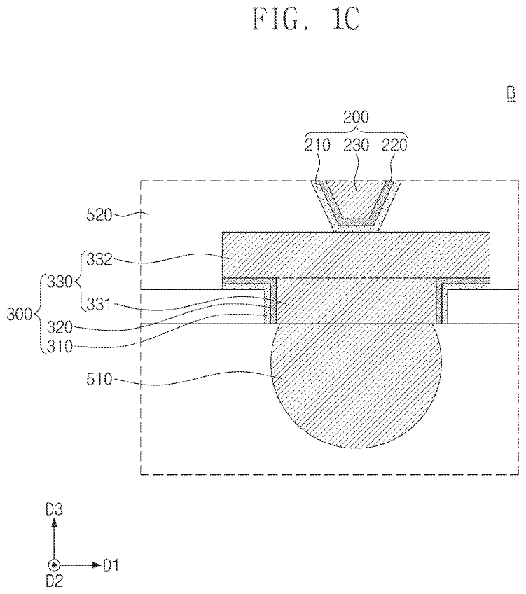

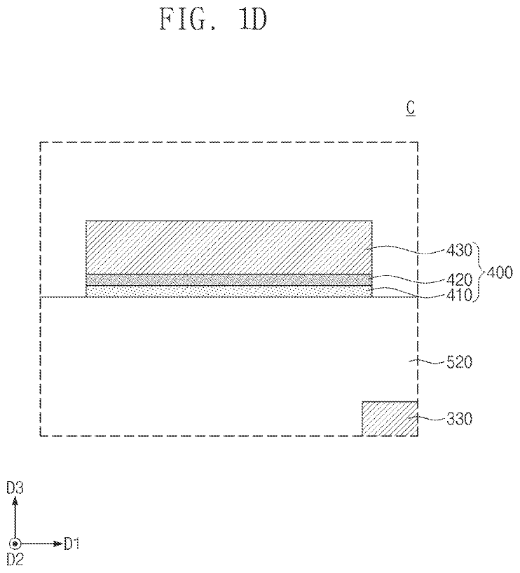

FIG. 1A is a sectional view illustrating a semiconductor package according to an embodiment of the present disclosure. FIG. 1B is a detailed view of a portion A of FIG. 1A. FIG. 1C is a detailed view of a portion B of FIG. 1A. FIG. 1D is a detailed view illustrating a portion ‘C’ of FIG. 1A.

Referring to FIG. 1A, a semiconductor package may include a redistribution substrate 700, solder balls 510, connection structures 530, a semiconductor chip 540, and a mold layer 550.

The redistribution substrate 700 may include insulating layers 520, first redistribution patterns 100, second redistribution patterns 200, connection conductive patterns 300, and horizontal redistribution patterns 400. A redistribution substrate refers to a substrate including a patterned conductive layer that provides a new set of connection points. The redistribution substrate may be used to re-route or redistribute the input/output (I/O) connections coming out of a chip to different locations. In integrated circuit designs, the I/O connections on a semiconductor chip may be not located in ideal locations for connecting to the next level of packaging. A redistribution substrate may be added to provide a new set of connection points as new locations, so that the connections from the original locations on the chip may be re-routed to these new locations.

The redistribution substrate 700 may be a plate-shaped structure extended in a first direction D1 and a second direction D2. The first and second directions D1 and D2 may be non-parallel. In an embodiment, the first and second directions D1 and D2 may be in horizontal directions and are orthogonal to each other.

The insulating layers 520 may be stacked in a third direction D3. The third direction D3 may be non-parallel to the first and second directions D1 and D2. In an example, the third direction D3 may be a vertical direction orthogonal to the first and second directions D1 and D2. The insulating layer 520 may be formed of or include at least one of organic materials (e.g., photoimageable dielectric (PID) materials). The photoimageable insulating materials may include at least one of, for example, photoimageable polyimides, polybenzoxazole, phenol-based polymers, or benzocyclobutene-based polymers.

The first redistribution patterns 100 may be disposed in an upper portion of the redistribution substrate 700. The first redistribution patterns 100 may be exposed to the outside of the redistribution substrate 700 in an upward direction. The first redistribution pattern 100 may include a first barrier layer 110, a second barrier layer 120, and a via structure 130. In some examples, the first redistribution pattern 100 may have a T-shaped section. However, embodiments of the present disclosure are not limited thereto. The first redistribution pattern 100 may vertically connect the connection structure 530 to the second redistribution pattern 200. The first redistribution pattern 100 may electrically connect the connection structure 530 and the second redistribution pattern 200.

The first barrier layer 110 may be formed of or include at least one conductive material. In an example, the first barrier layer 110 may be formed of or include TiN. The first barrier layer 110 may have a thickness in a range from 1 nm to 30 nm. The thickness of the first barrier layer 110 may be smaller than a thickness of the second barrier layer 120. The first barrier layer 110 may be in contact with the connection structure 530. The first barrier layer 110 may be surrounded by the connection structure 530 in a plan view. A bottom surface of the first barrier layer 110 may be in contact with a top surface of a via structure 230 of the second redistribution pattern 200.

The second barrier layer 120 may be formed of or include a conductive material different from the first barrier layer 110. In some cases, each of the first barrier layer 110 and the second barrier layer 120 may include a single material. In some cases, one or more of the first barrier layer 110 and the second barrier layer 120 may include multiple materials. In an example, the second barrier layer 120 may be formed of or include Ti. The second barrier layer 120 may have a thickness in a range from 1 nm to 500 nm. The second barrier layer 120 may be in contact with the connection structure 530. The second barrier layer 120 may be surrounded by the connection structure 530 in a plan view. The second barrier layer 120 may cover a top surface of the first barrier layer 110. The second barrier layer 120 may be disposed on the first barrier layer 110. The second barrier layer 120 may be in contact with the first barrier layer 110.

The via structure 130 may be exposed to the outside of the first redistribution pattern 100 in an upward direction. The via structure 130 may be formed of or include at least one conductive material. In an embodiment, the via structure 130 may be formed of or include at least one of copper (Cu), gold (Au), silver (Ag), or tin (Sn). The via structure 130 may be in contact with the connection structure 530. The via structure 130 may be surrounded by the connection structure 530 in a plan view. The via structure 130 may cover a top surface of the second barrier layer 120. The via structure 130 may be disposed on the second barrier layer 120. The via structure 130 may be in contact with the second barrier layer 120.

The second redistribution patterns 200 may be disposed in the redistribution substrate 700. The second redistribution pattern 200 may include a first barrier layer 210, a second barrier layer 220, and the via structure 230. In some examples, the second redistribution pattern 200 may have a T-shaped section. However, embodiments of the present disclosure are not limited thereto. The second redistribution pattern 200 may vertically connect the first redistribution pattern 100 to the connection conductive pattern 300. The second redistribution pattern 200 may electrically connect the first redistribution pattern 100 and the connection conductive pattern 300.

The first barrier layer 210, the second barrier layer 220, and the via structure 230 of the second redistribution pattern 200 may be similar to the first barrier layer 110, the second barrier layer 120, and the via structure 130 of the first redistribution pattern 100, respectively. The via structure 230 of the second redistribution pattern 200 may be in contact with a bottom surface of the first barrier layer 110 of the first redistribution pattern 100. The first barrier layer 210 of the second redistribution pattern 200 may be in contact with a top surface of an under-bump 330 of the connection conductive pattern 300.

The connection conductive patterns 300 may be disposed in a lower portion of the redistribution substrate 700. The connection conductive patterns 300 may be exposed to the outside of the redistribution substrate 700 in a downward direction. The connection conductive pattern 300 may include a first barrier layer 310, a second barrier layer 320, and the under-bump 330. The connection conductive pattern 300 may vertically connect the second redistribution pattern 200 to the solder ball 510. The connection conductive pattern 300 may electrically connect the second redistribution pattern 200 and the solder ball 510.

The first and second barrier layers 310 and 320 of the connection conductive pattern 300 may be similar to the first and second barrier layers 110 and 120 of the first redistribution pattern 100 respectively. The bottom surface of the under-bump 330 is uncovered by both the first and second barrier layers (310 and 320) of the connection conductive pattern 300. The bottom surface of the under-bump 330 of the connection conductive pattern 300 may be in contact with the solder ball 510. The under-bump 330 may be disposed on the second barrier layer 320 of the connection conductive pattern 300. The under-bump 330 may be formed of or include at least one conductive materials. In an example, the under-bump 330 may be formed of or include Cu.

The horizontal redistribution pattern 400 may include a first barrier layer 410, a second barrier layer 420, and a redistribution layer 430. The horizontal redistribution pattern 400 may be surrounded by the insulating layer 520 in a plan view.

The solder ball 510 may be connected to the under-bump 330 of the connection conductive pattern 300. The semiconductor package may be electrically connected to an external device through the solder ball 510. The solder ball 510 may be formed of or include at least one conductive material.

The connection structure 530 may electrically connect the first redistribution pattern 100 to the semiconductor chip 540. The connection structure 530 may be in contact with the first barrier layer 110, the second barrier layer 120, and the via structure 130 of the first redistribution pattern 100. The connection structure 530 may be formed of or include at least one conductive material.

The semiconductor chip 540 may include a semiconductor device. The semiconductor device may include, for example, a logic device, a memory device, or an image sensor device. However, embodiments of the present disclosure are not limited thereto.

The semiconductor chip 540 may include a substrate 541, an interconnection structure 542, pads 543, and a lower protection layer 544. The substrate 541 may be a semiconductor substrate. In an embodiment, the substrate 541 may be a silicon substrate or a germanium substrate.

The interconnection structure 542 may be disposed on a bottom surface of the substrate 541. The semiconductor device may be disposed between the interconnection structure 542 and the substrate 541. The pads 543 may be disposed in the interconnection structure 542. The interconnection structure 542 may include an interconnection insulating layer and a conductive structure in the interconnection insulating layer. The conductive structure of the interconnection structure 542 may electrically connect the semiconductor device to the pad 543. The interconnection insulating layer may be formed of or include an insulating material. The conductive structure and the pad 543 may be formed of or include at least one conductive material.

The lower protection layer 544 may be disposed on a bottom surface of the interconnection structure 542. The lower protection layer 544 may be formed of or include an insulating material.

The mold layer 550 may be disposed on the redistribution substrate 700. The mold layer 550 may surround the connection structure 530 and the semiconductor chip 540 in a plan view. The mold layer 550 may be spaced apart from the first redistribution pattern 100. The mold layer 550 may be spaced apart from the first barrier layer 110, the second barrier layer 120, and the via structure 130 of the first redistribution pattern 100. The mold layer 550 may be formed of or include at least one of polymer materials.

Referring to FIG. 1B, the first redistribution pattern 100 may electrically connect the connection structure 530 to the second redistribution pattern 200. The via structure 130 of the first redistribution pattern 100 may include a head portion 132 and a tail portion 131, which are connected to each other to form a single object. The head portion 132 and the tail portion 131 may be formed of or include at least one conductive material. For example, the head portion 132 and the tail portion 131 may be formed of or include at least one of copper (Cu), gold (Ag), silver (Ag), or tin (Sn). The head portion 132 and the tail portion 131 may be formed of or include the same metallic material. The head portion 132 may be used for a horizontal electric connection of the redistribution substrate 700. The head portion 132 and the tail portion 131 may be overlapped in the third direction D3, and there may be substantially no interface therebetween. A width of the head portion 132 may be larger than a width of the tail portion 131. In some examples, decreasing the vertical level may result in a reduction of width of the tail portion 131. The head portion 132 may be in contact with the connection structure 530. The head portion 132 may be surrounded by the connection structure 530 in a plan view. The tail portion 131 may be surrounded by the second barrier layer 120 in a plan view.

Referring to FIG. 1C, the under-bump 330 of the connection conductive pattern 300 may include a lower portion 331 and an upper portion 332, which are connected to each other to form a single object. A width of the lower portion 331 of the under-bump 330 may be smaller than a width of the upper portion 332 of the under-bump 330. The lower portion 331 of the under-bump 330 may be surrounded by the first and second barrier layers 310 and 320 in a plan view. A side surface of the lower portion 331 of the under-bump 330 may be in contact with the second barrier layer 320. A bottom surface of the upper portion 332 of the under-bump 330 may be in contact with the second barrier layer 320. A side surface of the upper portion 332 of the under-bump 330 may be in contact with the insulating layer 520. A bottom surface of the lower portion 331 of the under-bump 330 may be in contact with the solder ball 510. The upper portion 332 of the under-bump 330 may be in contact with the first barrier layer 210 of the second redistribution pattern 200. The under-bump 330 may be surrounded by the insulating layers 520 in a plan view.

Referring to FIG. 1D, the horizontal redistribution pattern 400 may be disposed on the insulating layer 520. The horizontal redistribution pattern 400 may be in contact with the insulating layer 520. The horizontal redistribution pattern 400 may be surrounded by the insulating layer 520 in a plan view.

The horizontal redistribution pattern 400 may be a pattern extending in a horizontal direction. For example, the horizontal redistribution pattern 400 may be bar-shaped. The first barrier layer 410, the second barrier layer 420, and the redistribution layer 430 of the horizontal redistribution pattern 400 may be patterns extending in a horizontal direction. For example, the first barrier layer 410, the second barrier layer 420, and the redistribution layer 430 of the horizontal redistribution pattern 400 may be bar-shaped. The first barrier layer 410, the second barrier layer 420, and the redistribution layer 430 of the horizontal redistribution pattern 400 may be the same as the first barrier layer 110, the second barrier layer 120, and the via structure 130 of the first redistribution pattern 100, respectively, in terms of materials and thicknesses.

In the semiconductor package according to an embodiment of the present disclosure, the redistribution patterns 100, 200, and 400 and the connection conductive pattern 300 may include the first barrier layers 110, 210, 310, and 410, which are formed of or include titanium nitride (TiN), and thus, the second barrier layers 120, 220, 320, and 420 may not be oxidized by a gas outgassed from the insulating layer 520. As a result, the redistribution patterns 100, 200, and 400 and the connection conductive pattern 300 may avoid being oxidized. Due to this oxidation prevention effect, it may be possible to prevent a delamination phenomenon of the redistribution patterns 100, 200, and 400 and the connection conductive pattern 300 from the insulating layer 520; that is, the redistribution patterns 100, 200, and 400 and the connection conductive pattern 300 may be more robustly attached to the insulating layer 520.

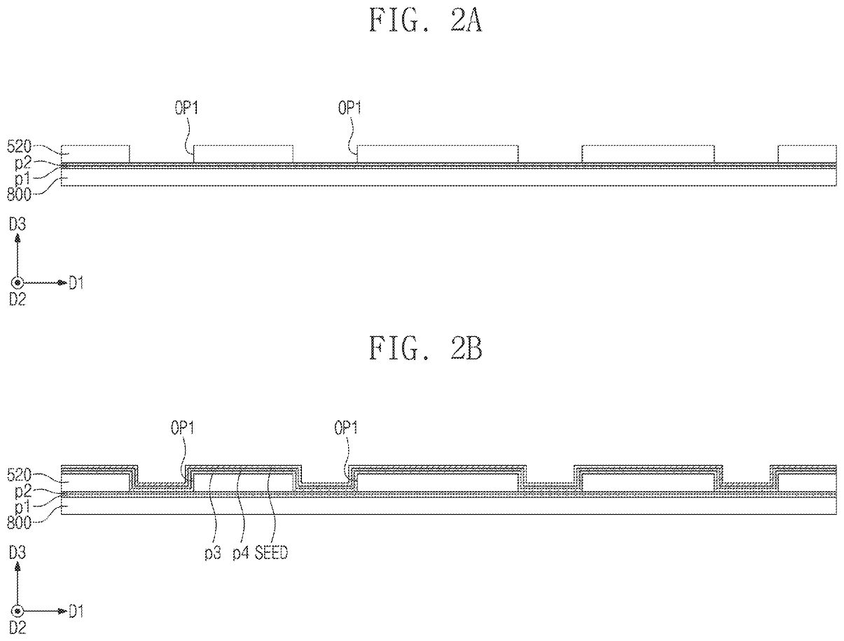

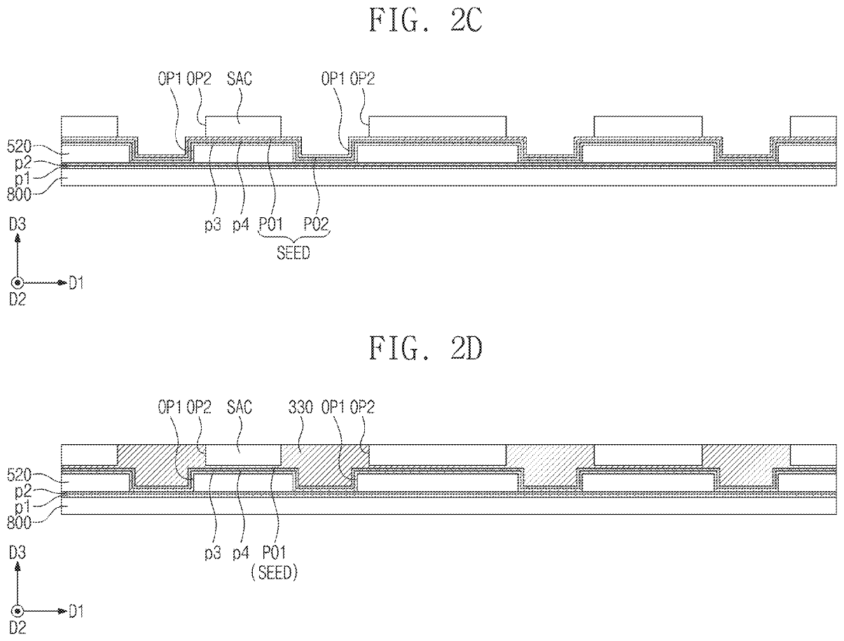

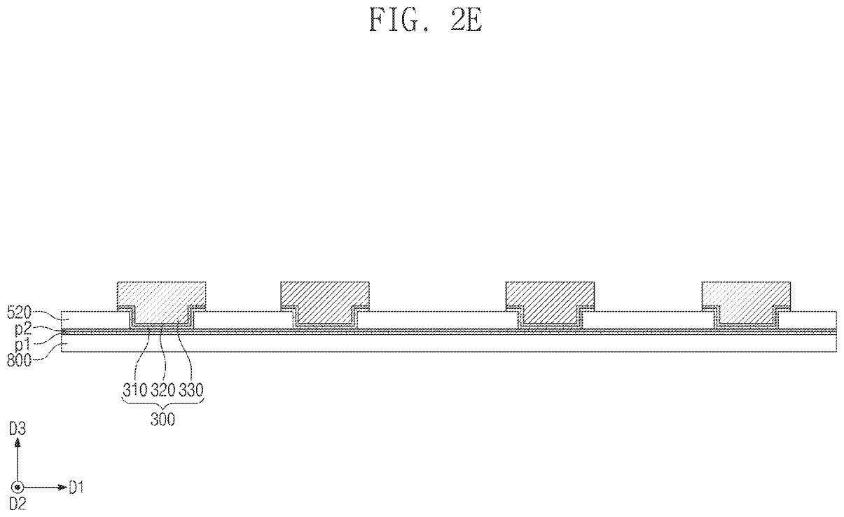

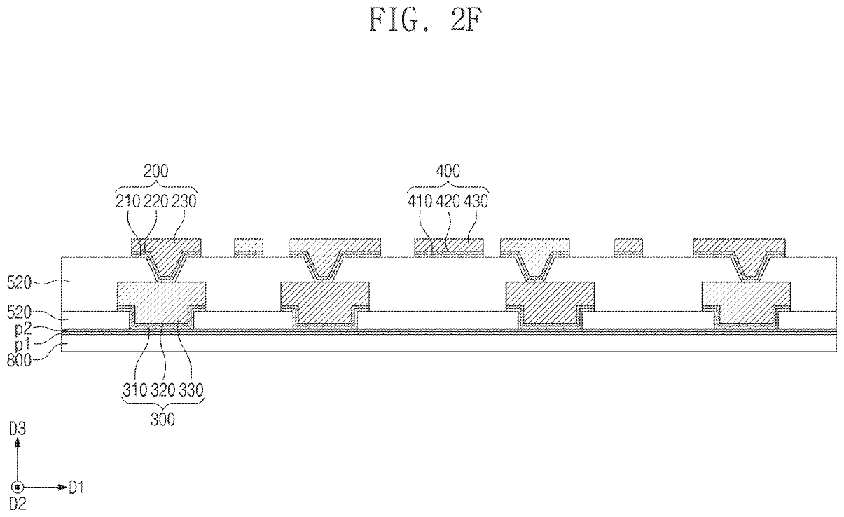

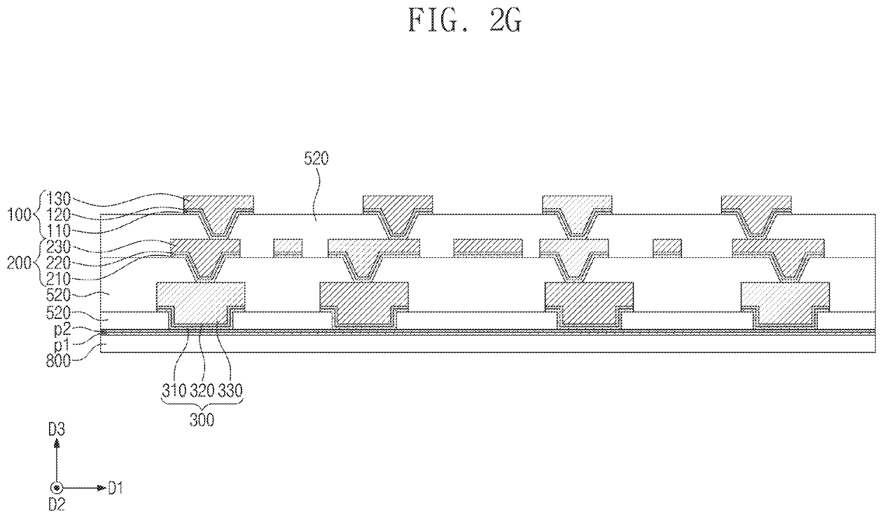

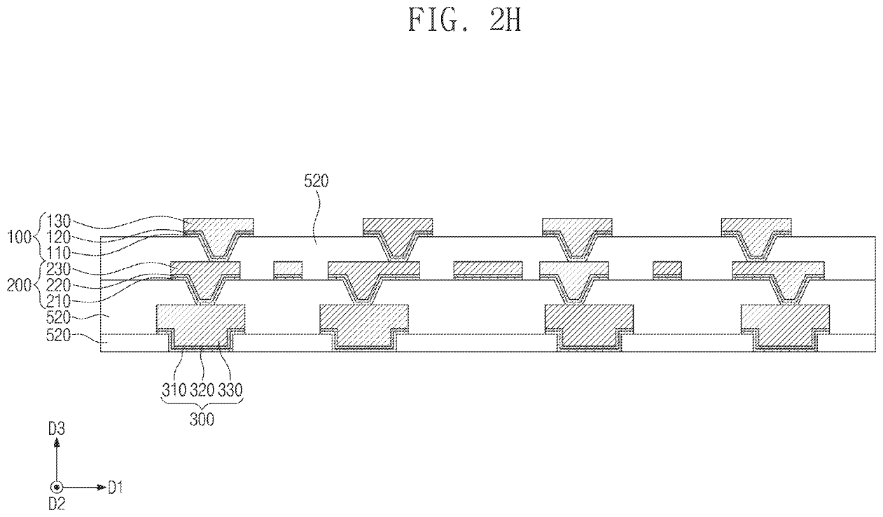

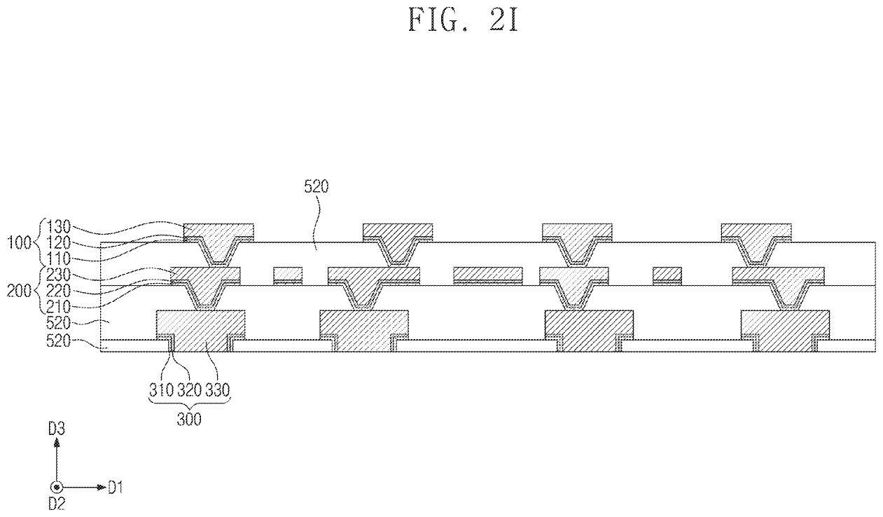

FIGS. 2A, 2B, 2C, 2D, 2E, 2F, 2G, 2H, and 2I are sectional views illustrating a method of fabricating a semiconductor package according to an embodiment of the present disclosure. Referring to FIG. 2A, a protection layer 800, a first preliminary barrier layer p1 on the protection layer 800, and a second preliminary barrier layer p2 on the first preliminary barrier layer p1 may be formed.

The first and second preliminary barrier layers p1 and p2 may be formed by, for example, a physical vapor deposition (PVD) process. The first preliminary barrier layer p1 may be formed of or include a first conductive material, and the second preliminary barrier layer p2 may be formed of or include a second conductive material different from the first conductive material.

The protection layer 800 may be formed of or include at least one of organic materials (e.g., photoimageable dielectric (PID) materials). The photoimageable insulating materials may include at least one of, for example, photoimageable polyimides, polybenzoxazole, phenol-based polymers, or benzocyclobutene-based polymers. The first preliminary barrier layer p1 may be formed on the protection layer 800 and may prevent the second preliminary barrier layer p2 from being oxidized by a gas outgassed from the protection layer 800.

The insulating layer 520 may be formed on the second preliminary barrier layer p2. The insulating layer 520 may be formed by, for example, a polyimide (PI) coating process.

The first openings OP1 may be formed in an insulating layer 522. The second preliminary barrier layer p2 may be exposed to the outside through the first openings OP1. Referring to FIG. 2B, a third preliminary barrier layer p3 may be conformally formed on the insulating layer 520 and the second preliminary barrier layer p2. For example, a third preliminary barrier layer p3 may be evenly applied over the insulating layer 520 and the second preliminary barrier layer p2, adhering to their shapes and contours closely. A fourth preliminary barrier layer p4 may be conformally formed on the third preliminary barrier layer p3. For example, a fourth preliminary barrier layer p4 may be uniformly applied over the third preliminary barrier layer p3, adhering to its shape and contours closely. A seed layer SEED may be conformally formed on the fourth preliminary barrier layer p4. For example, a seed layer SEED may be uniformly applied over the fourth preliminary barrier layer p4, adhering to its shape and contours closely. The third and fourth preliminary barrier layers p3 and p4 may be formed by, for example, a physical vapor deposition (PVD) process. The third and fourth preliminary barrier layers p3 and p4 may be formed of or include different conductive materials from each other. The seed layer SEED may be formed of or include at least one conductive material. For example, the seed layer SEED may be formed of or include Cu.

Referring to FIG. 2C, a sacrificial layer SAC may be formed on the seed layer SEED. A sacrificial layer refers to a layer of material that is deposited onto a structure and is to be later removed in semiconductor fabrication. For example, the sacrificial layer may used to shape, protect, or otherwise manipulate the structure beneath it during semiconductor fabrication. The sacrificial layer SAC may be formed of or include the same insulating material as the insulating layer 520. Second openings OP2 may be formed in the sacrificial layer SAC. The second opening OP2 may be overlapped with the first opening OP1 in the third direction D3. A width of the second opening OP2 may be larger than a width of the first opening OP1. The seed layer SEED may include a first portion PO1, which is covered with the sacrificial layer SAC, and a second portion PO2, which is exposed through the first and second openings OP1 and OP2.

Referring to FIG. 2D, the under-bumps 330 may be formed. The formation of the under-bumps 330 may include performing an electroplating process, in which the second portion PO2 of the seed layer SEED is used as a seed. The electroplating process includes using an electric current to reduce dissolved metal cations to form a coherent metal coating on an electrode. A seed in electroplating refers to an initial layer that the electroplated metal which forms the under-bump adheres to. For example, the second portion PO2 of the seed layer SEED may be the initial layer. The under-bump 330 may be formed to fill the first and second openings OP1 and OP2.

Referring to FIG. 2E, the sacrificial layer SAC may be removed. The first portion PO1 of the seed layer SEED may be removed. The fourth and third preliminary barrier layers p4 and p3 may be etched. The second barrier layer 320 of the connection conductive pattern 300 may be formed as a result of etching the fourth preliminary barrier layer p4. The first barrier layer 310 of the connection conductive pattern 300 may be formed as a result of the etching of the third preliminary barrier layer p3. For example, by etching away portions of the fourth preliminary barrier layer p4, the second barrier layer 320 is formed in the connection conductive pattern 300.

Referring to FIG. 2F, the insulating layer 520 may be formed to cover the connection conductive patterns 300. The second redistribution patterns 200 and the horizontal redistribution patterns 400 may be formed by a method that is similar to that for the connection conductive pattern 300.

Referring to FIG. 2G, the insulating layer 520 may be formed to cover the second redistribution patterns 200 and the horizontal redistribution patterns 400. For example, the insulating layer 520 may be formed to surround the second redistribution patterns 200 and the horizontal redistribution patterns 400 in a plan view. The first redistribution patterns 100 may be formed by a method that is similar to that for the connection conductive pattern 300.

Referring to FIG. 2H, the protection layer 800 may be removed. Thereafter, the first and second preliminary barrier layers p1 and p2 may be removed. As a result of the removal of the second preliminary barrier layer p2, a bottom surface of the first barrier layer 310 of the connection conductive pattern 300 may be exposed to the outside.

Referring to FIG. 2I, lower portions of the first and second barrier layers 310 and 320 of the connection conductive pattern 300 may be removed. As a result, a bottom surface of the under-bump 330 may be exposed to the outside.

Referring to FIG. 1A, the connection structure 530 and the semiconductor chip 540 may be formed on the first redistribution pattern 100. The mold layer 550 may be formed to surround the semiconductor chip 540 and the connection structure 530 in a plan view. The solder ball 510, which is connected to the connection conductive pattern 300, may be formed.

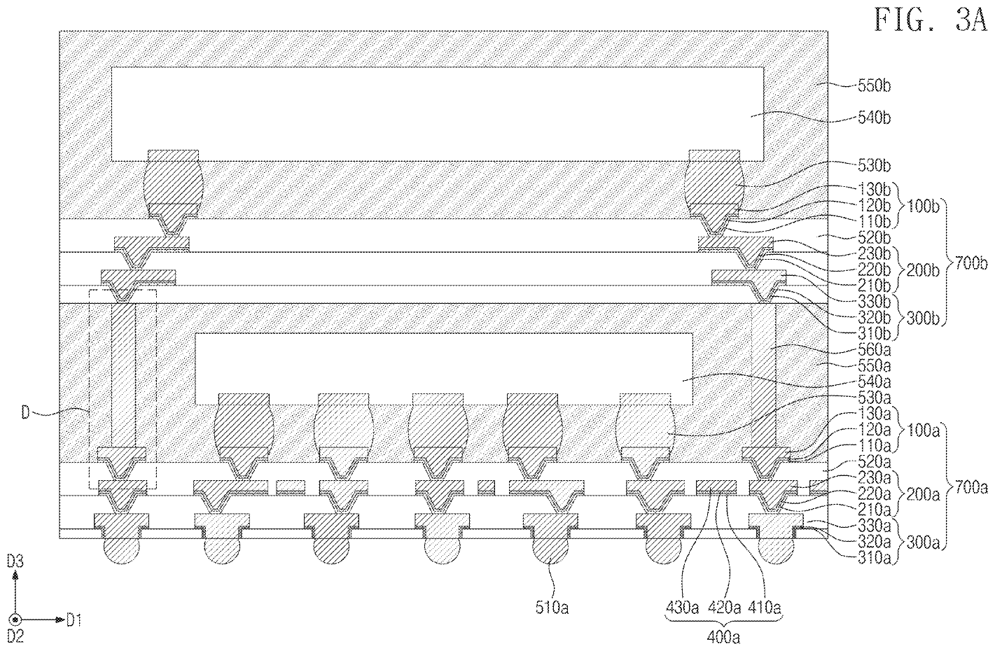

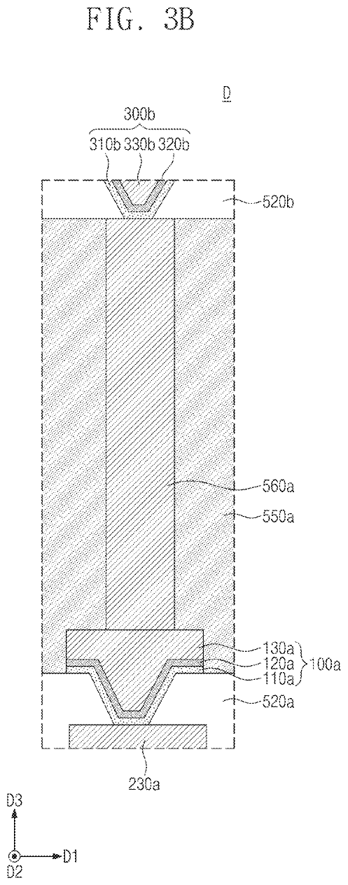

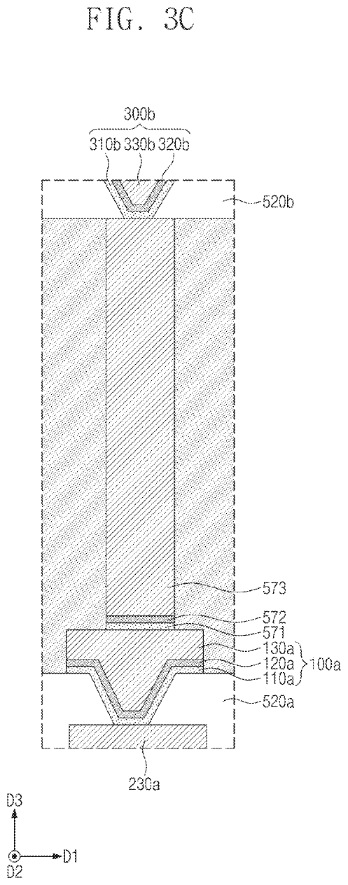

FIG. 3A is a sectional view illustrating a semiconductor package according to an embodiment of the present disclosure. FIG. 3B is a detailed view illustrating a portion ‘D’ of FIG. 3A.

Referring to FIG. 3A, a semiconductor package may include a first redistribution substrate 700a, a second redistribution substrate 700b, solder balls 510a, a first connection structures 530a, a second connection structures 530b, a first semiconductor chip 540a, a second semiconductor chip 540b, a first mold layer 550a, a second mold layer 550b, and a post 560a.

The first redistribution substrate 700a may include a first redistribution pattern 100a, a second redistribution pattern 200a, a connection conductive pattern 300a, a horizontal redistribution pattern 400a, and first insulating layers 520a.

The first redistribution pattern 100a may include a first barrier layer 110a, a second barrier layer 120a on the first barrier layer 110a, and a via structure 130a on the second barrier layer 120a. The first redistribution pattern 100a may be in contact with the post 560a.

The second redistribution pattern 200a may include a first barrier layer 210a, a second barrier layer 220a on the first barrier layer 210a, and a via structure 230a on the second barrier layer 220a.

The connection conductive pattern 300a may include a first barrier layer 310a, a second barrier layer 320a on the first barrier layer 310a, and an under-bump 330a on the second barrier layer 320a. In some cases, each of the first barrier layer 310a and the second barrier layer 320a may include a single material. In some cases, one or more of the first barrier layer 310a and the second barrier layer 320a may include multiple materials.

The second redistribution substrate 700b may include a third redistribution pattern 100b, a fourth redistribution pattern 200b, and a fifth redistribution pattern 300b.

The third redistribution pattern 100b may include a first barrier layer 110b, a second barrier layer 120b on the first barrier layer 110b, and a via structure 130b on the second barrier layer 120b. The third redistribution pattern 100b may be formed on the fourth redistribution pattern 200b. The third redistribution pattern 100b may be in contact with the fourth redistribution pattern 200b. The third redistribution pattern 100b may be in contact with the second connection structure 530b. The third redistribution pattern 100b may electrically connect the second connection structure 530b to the fourth redistribution pattern 200b.

The fourth redistribution pattern 200b may include a first barrier layer 210b, a second barrier layer 220b on the first barrier layer 210b, and a via structure 230b on the second barrier layer 220b. The fourth redistribution pattern 200b may be formed on the fifth redistribution pattern 300b. The fourth redistribution pattern 200b may be in contact with the fifth redistribution pattern 300b. The fourth redistribution pattern 200b may electrically connect the third redistribution pattern 100b to the fifth redistribution pattern 300b.

The fifth redistribution pattern 300b may include a first barrier layer 310b, a second barrier layer 320b on the first barrier layer 310b, and a via structure 330b on the second barrier layer 320b. The fifth redistribution pattern 300b may be disposed on the post 560a. The fifth redistribution pattern 300b may be in contact with the post 560a.

The first semiconductor chip 540a may be mounted on the first redistribution substrate 700a. The first semiconductor chip 540a may be surrounded by the first mold layer 550a in a plan view.

The second semiconductor chip 540b may be mounted on the second redistribution substrate 700b. The second semiconductor chip 540b may be surrounded by the second mold layer 550b in a plan view.

Referring to FIG. 3B, the post 560a may be formed on the first redistribution pattern 100a. The post 560a may electrically connect the first redistribution substrate 700a to the second redistribution substrate 700b. A bottom surface of the post 560a may be in contact with a top surface of the via structure 130a of the first redistribution pattern 100a of the first redistribution substrate 700a. A top surface of the post 560a may be in contact with the first barrier layer 310b of the fifth redistribution pattern 300b of the second redistribution substrate 700b. The post 560a may be surrounded by the first mold layer 550a in a plan view.

FIG. 3C is a detailed sectional view illustrating a semiconductor package according to an embodiment of the present disclosure. Except for technical features to be described below, the elements in FIG. 3C may be configured to have technical features that are similar to those in FIG. 3A and 3B.

Referring to FIG. 3C, a first post barrier layer 571 may be disposed on the first redistribution pattern 100a. A second post barrier layer 572 may be disposed on the first post barrier layer 571. A post 573 may be disposed on the second post barrier layer 572.

The first post barrier layer 571 may be formed of or include at least one conductive material. In some cases, each of the first post barrier layer 571 and the second post barrier layer 572 may include a single material. In some cases, one or more of the first post barrier layer 571 and the second post barrier layer 572 may include multiple materials. In an example, the first post barrier layer 571 may be formed of or include Ti or TiN. The second post barrier layer 572 may be formed of or include a conductive material different from the first post barrier layer 571. In an example, the second post barrier layer 572 may be formed of or include Ti.

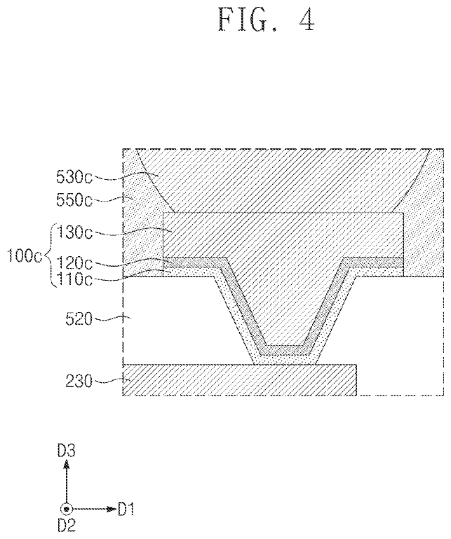

FIG. 4 is a detailed sectional view illustrating a semiconductor package according to an embodiment of the present disclosure.

Referring to FIG. 4, a redistribution pattern 100c of a semiconductor package may be in contact with a connection structure 530c. The redistribution pattern 100c may include a first barrier layer 110c, a second barrier layer 120c, and a via structure 130c. The connection structure 530c may be in contact with a top surface of the via structure 130c. The connection structure 530c may be spaced apart from the first and second barrier layers 110c and 120c. The first barrier layer 110c, the second barrier layer 120c, and the via structure 130c may be in contact with a mold layer 550c.

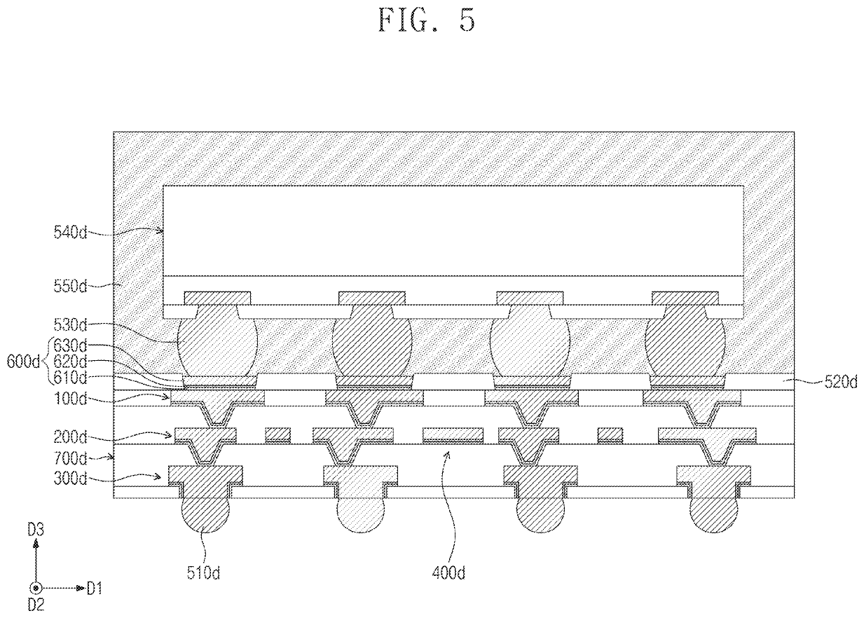

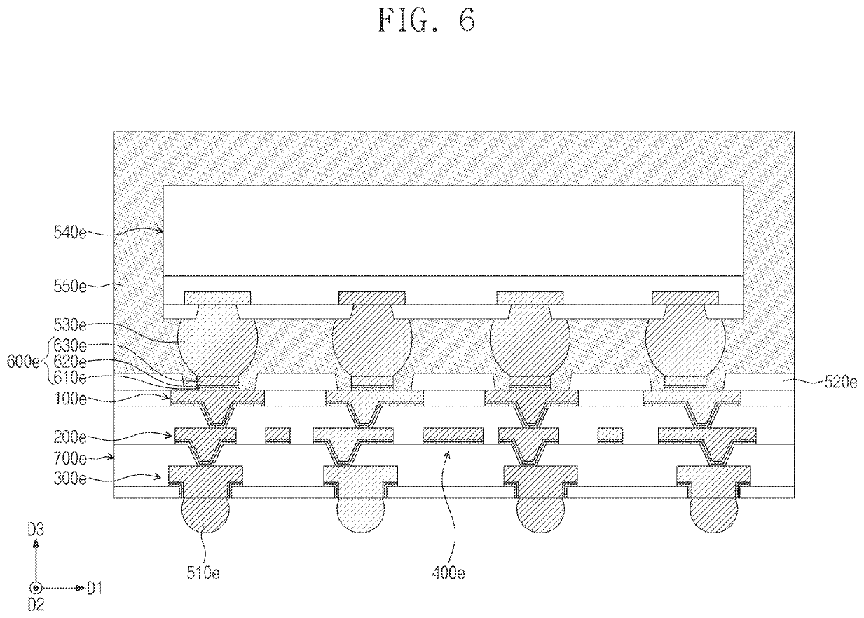

FIG. 5 is a sectional view illustrating a semiconductor package according to an embodiment of the present disclosure.

Referring to FIG. 5, a semiconductor package may include a redistribution substrate 700d, solder balls 510d, connection structures 530d, a semiconductor chip 540d, and a mold layer 550d.

The redistribution substrate 700d may include insulating layers 520d, first redistribution patterns 100d, second redistribution patterns 200d, connection conductive patterns 300d, horizontal redistribution patterns 400d, and pad redistribution patterns 600d.

The pad redistribution pattern 600d may be disposed on the first redistribution pattern 100d. The connection structure 530d may be disposed on the pad redistribution pattern 600d. The pad redistribution pattern 600d may include a first barrier layer 610d, a second barrier layer 620d, and a pad layer 630d. The first and second barrier layers 610d and 620d of the pad redistribution pattern 600d may be formed of or include different conductive materials from each other.

The pad redistribution pattern 600d may be surrounded by the insulating layer 520d in a plan view. Side surfaces of the first barrier layer 610d, the second barrier layer 620d, and the pad layer 630d of the pad redistribution pattern 600d may be in contact with the insulating layer 520d.

FIG. 6 is a sectional view illustrating a semiconductor package according to an embodiment of the present disclosure.

Referring to FIG. 6, a semiconductor package may include a redistribution substrate 700e, solder balls 510e, connection structures 530e, a semiconductor chip 540e, and a mold layer 550e.

The redistribution substrate 700e may include insulating layers 520e, first redistribution patterns 100e, second redistribution patterns 200e, connection conductive patterns 300e, horizontal redistribution patterns 400e, and pad redistribution patterns 600e.

The pad redistribution pattern 600e may be disposed on the first redistribution pattern 100e. The connection structure 530e may be disposed on the pad redistribution pattern 600e. The pad redistribution pattern 600e may include a first barrier layer 610e, a second barrier layer 620e, and a pad layer 630e. The first and second barrier layers 610e and 620e of the pad redistribution pattern 600e may be formed of or include different conductive materials from each other.

The pad redistribution pattern 600e may be surrounded by the mold layer 550e in a plan view. Side surfaces of the first barrier layer 610e, the second barrier layer 620e, and the pad layer 630e of the pad redistribution pattern 600e may be spaced apart from the insulating layer 520e. The side surfaces of the first barrier layer 610e, the second barrier layer 620e, and the pad layer 630e of the pad redistribution pattern 600e may be in contact with the mold layer 550e. A portion of the mold layer 550e may be interposed between the insulating layer 520e and the pad redistribution pattern 600e.

According to an embodiment of the present disclosure, a semiconductor package may include a redistribution pattern including a first barrier layer and a second barrier layer, and in this case, it may be possible to enhance an adhesion strength between an insulating layer and the redistribution pattern.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor package, comprising:
a redistribution substrate including an insulating layer and a first redistribution pattern; and
a semiconductor chip electrically connected to the redistribution substrate,
wherein the first redistribution pattern comprises:
a first barrier layer;
a second barrier layer on the first barrier layer; and
a via structure on the second barrier layer,
wherein the first barrier layer comprises a first conductive material and the second barrier layer comprises a second conductive material different from the first conductive material.

2. The semiconductor package of claim 1, wherein the first conductive material comprises titanium nitride (TiN).

3. The semiconductor package of claim 1, wherein the second conductive material comprises titanium (Ti).

4. The semiconductor package of claim 1, wherein the first barrier layer has a thickness in a range from 1 nm to 30 nm.

5. The semiconductor package of claim 1, wherein the second barrier layer has a thickness in a range from 1 nm to 500 nm.

6. The semiconductor package of claim 1, wherein a thickness of the first barrier layer is smaller than a thickness of the second barrier layer.

7. The semiconductor package of claim 1, further comprising a connection structure connecting the semiconductor chip to the redistribution substrate and a mold layer surrounding the semiconductor chip in a plan view,
wherein the first barrier layer, the second barrier layer, and the via structure are in contact with the connection structure, and
the mold layer is spaced apart from the first barrier layer and the second barrier layer.

8. The semiconductor package of claim 1, wherein the redistribution substrate further comprises a second redistribution pattern connected to the first redistribution pattern, and
the second redistribution pattern comprises a via structure in contact with a bottom surface of the first barrier layer of the first redistribution pattern.

9. The semiconductor package of claim 1, wherein the via structure comprises copper (Cu).

10. The semiconductor package of claim 1, further comprising a post on the first redistribution pattern.

11. A semiconductor package, comprising:
a redistribution substrate including an insulating layer, a redistribution pattern, and a connection conductive pattern;
a semiconductor chip electrically connected to the redistribution substrate; and
a solder ball in contact with the connection conductive pattern,
wherein the connection conductive pattern comprises:
an under-bump including an upper portion and a lower portion having a width smaller than the upper portion; and
a first barrier layer and a second barrier layer, wherein each of the first barrier layer and the second barrier layer surrounds the lower portion of the under-bump in a plan view,
wherein the solder ball is in contact with a bottom surface of the lower portion of the under-bump.

12. The semiconductor package of claim 11, wherein the first barrier layer comprises titanium nitride (TiN), and
the second barrier layer comprises titanium (Ti).

13. The semiconductor package of claim 12, wherein the under-bump comprises copper (Cu).

14. The semiconductor package of claim 11, wherein the first barrier layer has a thickness in a range from 1 nm to 30 nm, and
the second barrier layer has a thickness in a range from 1 nm to 500 nm.

15. The semiconductor package of claim 11, further comprising a post on the redistribution pattern.

16. The semiconductor package of claim 11, wherein the redistribution pattern comprises:
a first redistribution barrier layer;
a second redistribution barrier layer on the first redistribution barrier layer; and
a via structure on the second redistribution barrier layer.

17. The semiconductor package of claim 16, further comprising a connection structure connecting the semiconductor chip to the redistribution substrate,
wherein the connection structure is in contact with the first redistribution barrier layer, the second redistribution barrier layer, and the via structure.

18. A semiconductor package, comprising:
a first redistribution substrate including an insulating layer, a first redistribution pattern, a second redistribution pattern, and a connection conductive pattern;
a first semiconductor chip mounted on the first redistribution substrate;
a connection structure between the first semiconductor chip and the first redistribution pattern; and
a solder ball connected to the connection conductive pattern,
wherein each of the first and the second redistribution patterns comprises:
a first barrier layer;
a second barrier layer on the first barrier layer; and
a via structure on the second barrier layer,
wherein the first barrier layer comprises titanium nitride (TiN),
the second barrier layer comprises titanium (Ti),
the via structure comprises copper (Cu), and
a thickness of the first barrier layer is smaller than a thickness of the second barrier layer.

19. The semiconductor package of claim 18, further comprising a post on the first redistribution pattern and a second redistribution substrate on the post.

20. The semiconductor package of claim 19, further comprising a second semiconductor chip mounted on the second redistribution substrate.
